(19) United States
(12) Patent Application Publication
(10) Pub. No.: US 2007/0033508 A1
(43) Pub. Date: Feb. 8, 2007

(54) Interative stripewise trellis-based symbol detection method and device for multi-dimensional recording systems

(75) Inventors: Andries Pieter Hekstra, Eindhoven (NL); Willem Marie Julia Marcel Coene, Eindhoven (NL); Albert Hendrik Jan Immink, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 10/556,008

(22) PCT Filed: May 11, 2004
(86) PCT No.: PCT/IB04/50633

§ 371 Date: Nov. 8, 2005

(30) Foreign Application Priority Data
May 12, 2003 (EP) 03076440.1

(51) Int. Cl. H03M 13/03

(52) U.S. Cl. 714/795

(57) ABSTRACT

When processing a two dimensional data area it is known to be advantageous to divide the two dimensional are into stripes and process each stripe using a stripe-wise detector. The stripe being processed shifts row per row downwards. Each stripe has as its output the bit-decisions of the top bit-row of the stripe which is the most reliable. That output bit-row is also used as side-information for the bit detection of the next stripe which is the stripe which is shifted one bit-row downwards. The bit-row just across the bottom of the stripe on the other hand still needs to be determined in the current iteration, so only the initialisation bit-values can be used in the first iteration of the stripe-wise bit-detector. In order to prevent the propagation of errors towards the top bit row of the stripe the relative weight for the bottom branch bit in the figure-of-merit is reduced from the full 100% to a lower fraction.

### FIELD OF THE INVENTION

The invention relates to a trellis-based symbol detection method for detecting symbols of a channel data block recorded on a record carrier. The invention applies to digital recording systems, such as magnetic recording and optical recording systems. It is particularly advantageous for two-dimensional optical recording, which is one of the potential technologies for the next generations of optical recording.

### BACKGROUND ART

Current state-of-the-art optical disc systems are based on one-dimensional (ID) Optical Recording. A single laser beam is directed at a single track of information, which forms a continuous spiral on the disc, spiraling outwards to the outer edge of the disc. The single spiral contains a single (or one dimensional, ID) track of bits. The single track consists of sequences of very small pit-marks or pits and the spaces between them, which are called land-marks or lands. The laser light is diffracted at the pit structures of the track. The reflected light is detected on a photo-detector Integrated Circuit (IC), and a single high-frequency signal is generated, which is used as the waveform from which bit-decisions are derived. A new route for the 4th generation of optical recording technology that will succeed “Blue Ray Disc” also called “DVR” already succeeding DVD (Digital Video Disc) technology is based on two-dimensional (2D) binary optical recording. 2D recording means that e.g. 10 tracks are recorded in parallel on the disc without guard space in between. Then, the 10 tracks together form one big spiral. The format of a disc for 2D optical recording (called in short a “2D disc”) is based on that broad spiral, in which the information is recorded in the form of 2D features. The information is written as a honeycomb structure and is encoded with a 2D channel code, which facilitates bitdetection. The disc shall be read out with an array of e.g. 10 (or more) optical spots, which are sampled in time, in order to obtain a two dimensional array of samples in the player. Parallel read out is realized using a single laser beam, which passes through a grating, which produces the array of laser spots. The array of spots scans the full width of the broad spiral. The light from each laser spot is reflected by the 2D pattern on the disc, and is detected on a photo-detector IC, which generates a number of high frequency signal waveforms. The set of signal waveforms is used as the input of the 2D signal processing. The motivation behind 2D recording is that much less disc space is wasted as guard space, so that the recording capacity of the disc can be increased. Although 2D recording is first studied for optical recording, similarly, magnetic recording can also be made two-dimensional. One of the new aspects of such recording techniques is that they require two dimensional signal processing. In particular, one optical spot must be considered as a device which takes a plane of “pits”/“lands” (or “marks” and “non-marks”) as input and produces a corresponding output. The optical spot transfer function has the characteristics of a 2D low pass filter, whose shape can be approximated by a cone. Apart from its linear transfer characteristics, the 2D optical channel also has non-linear contributions. The radius of the cone corresponds to the cutoff frequency, determined by the numerical aperture of the lens, and the wavelength of the light. This filtering characteristic causes 2D Inter Symbol Interference (ISI) in the player. It is the task of a bit-detector to annihilate (most of) this ISI (which can be both linear and nonlinear). An optimal way to implement a bit-detector is to use a Viterbi algorithm. A Viterbi bit detector does not amplify the noise. If soft decision output, i.e. reliability information about the bits, is required, a dual-Viterbi i.e. (Max-)(Log-)MAP, or MAP, or SOVA (Soft Output Viterbi) algorithm can be used. One of the difficulties of designing a bit-detector for the 2D case, is that a straightforward Viterbi bit-detector would need as its “state”, one or more columns of “old” track bits because of the memory of the ISI. If e.g. 10 tracks are recorded in parallel in the 2D broad spiral, and e.g. two old bits per track is needed for a proper description of the state because of the tangential extent (along-the-tracks) of the 2D impulse response, this results in a state of 2×10=20 bits. Thus, the number of states in the Viterbi (or MAP, (Max-)(Log-)MAP, MAP, SOVA, etc.) algorithm becomes 2²⁰, which is completely impractical. This requires a different approach, which may be slightly sub optimal, but has a significantly reduced complexity. By providing a method of stripe wise bit detection where the stripe wise detector uses side information from adjacent tracks the bit detection of a broad spiral can be segmented, reducing the complexity of the overall detection method. The use of side information however can introduced errors into the bit detection.

### SUMMARY OF THE INVENTION

It is an object of the invention to provide a symbol detection method that does not degrade in performance due to unreliable side information.

To achieve this objective the bit detection method is characterized in that a weighing of a contribution of the side information is assigned based on a reliability of the side information

When, due to the nature of the source of the side information, the side information is not reliable the contribution to the bit detection of this side information is reduced by applying a weighing factor in accordance with the reliability of the side information. The contribution of unreliable side information receives a lower weighing factor then the contribution of reliable side information.

An embodiment of the symbol detection method is characterized in that the contribution is a contribution to an objective function of the search based algorithm.

An objective function of a search based algorithm is typically minimizing the error between the transmitted or recorded data and the detected data by searching among all candidate possibilities the most likely candidate. The contribution can be a contribution to a branch metric.

An embodiment of the symbol detection method is characterized in that the search based algorithm comprises the use of internal contributions and that the use of the internal contributions comprises assigning an individual weighing of the internal contributions.

In addition to weighing the contribution of the side information from outside the stripe the contributions from within the stripe can also be weighed to reduce contribution from unreliable parts of the stripe.

For instance the detection of bits in a row directly adjacent to a yet to be processed stripe is unreliable because all bits around a bit to be detected contribute to the detection of that bit but only the bits inside the stripe are contributing to the detection with their most likely values while the value of the bits outside the stripe but still contributing to the detection of that bit are less reliable and in a first iteration even unknown.

The weighing of the contribution of that bit, although inside the stripe, must be reduced in order to reduce the contribution from the unreliable bits just outside the stripe. If the bits outside the strip that contribute to the detection are not yet known, they can be assumed to all have the value 0, 1 or have a random value in order to have a value for the bit detection, even if that value is incorrect.

The bit being detected is thus less reliable and because the bit being detected is also used in the detection of its neighbors, those neighbors also receive contributions that are less reliable than desirable.

The weighing of the contribution of the bit to the detection of other bits in the stripe must thus also be reduced resulting in potentially different weighing of the contributions from inside the stripe.

An embodiment of the symbol detection method is characterized in that the search based algorithm is a Viterbi algorithm, a sequential decoding algorithm such as a stack algorithm or a Fano algorithm, or a soft-decision output algorithm such as a (Max)(Log)MAP algorithm, or a reduced complexity maximum likelihood detection algorithm.

The listed search based algorithms all can be used to perform bit detection, allow the introduction of contribution of side information and allow the weighing of contributions. They are there fore suitable algorithms that can be used with the bit detection method according to the invention.

An embodiment of the symbol detection method is characterized in that the side information is an estimated channel input symbol.

Hard decision bit detection methods produce side information in the form of an estimated channel input symbol. The contribution of the estimated channel input symbol is used during bit detection.

An embodiment of the symbol detection method is characterized in that the side information is likelihood information about a channel input symbol Soft decision bit detection algorithms produce side information in the form of likelihood information about a channel input symbol. The likelihood information of the estimated input symbol is used during bit detection.

An embodiment of the symbol detection method is characterized in that a further side information, derived from the row adjacent to the first stripe, is being used in the estimation of said symbol values.

Not only side information derived from channel input symbols can be used but also other side information derived from the adjacent stripe can be used. All side information derived from the adjacent stripe contribute to a more reliable bit detection.

An embodiment of the symbol detection method is characterized in that the further side information comprises channel output values.

Not only side information derived from channel input symbols can be used but also other side information derived from the channel output values of the adjacent stripe can be used. This additional side information when used in tandem with the side information derived from the estimated input symbols contributes to a more reliable bit detection.

An embodiment of the symbol detection method is characterized in that the channel output values are filtered channel output values.

Filtered output values are often readily available and can be used to derive side information from.

An embodiment of the symbol detection method is characterized in that a weighing of the contribution of the side information is highest for side information derived from a symbol detection with a highest reliability.

There can be multiple adjacent or overlapping stripes for a stripe to be processed. Each adjacent stripe then provides side information. In order to improve the bit detection of the stripe to be processed each contribution from the side information of the adjacent stripes is weighed and more reliable contribution are given a higher weight than less reliable contributions. This way the less reliable contributions contribute less to the bit detection resulting in a more reliable bit detection.

An embodiment of the symbol detection method is characterized in that the symbol detection with the highest reliability is a symbol detection from a previous iteration. With every iteration the reliability of the side information derived from the bit detection of that iteration increases because the reliability of the overall bit detection increases with every iteration.

Thus the weightings can be increased from one iteration to the next to reflect this increased reliability of the side information.

An embodiment of the symbol detection method is characterized in that the weighing is based on a distance between a position of a symbol value to be detected and a position of a side information symbol position.

When side information is located further away from the position of the symbol value to be detected the contribution of that side information is less than when the side information is located close to the symbol value to be detected. The weighing reflects this reduced contribution. This assures that side information from further away from the symbol value to be detected contributes less to the symbol detection.

An embodiment of the symbol detection method is characterized in that the distance is a distance to a most reliable side information position and that the weighing is a highest weighing.

The side information derived from the closest distance has the largest contribution to the symbol detection.

The weighing reflects this contribution by assigning the highest weight to the contribution of this side information.

An embodiment of the symbol detection method is characterized in that the weighing of the contribution of the side information is different for the second detector compared to the first detector

When the stripe is processed by multiple bit detectors in parallel the weighing of contributions can differ from one detector to another detector, for instance because the reliability of the symbol detection from which the side information is derived varies from stripe to stripe across the broad spiral which the stripes together form.

An embodiment of the symbol detection method is characterized in that the weighing of the contribution of the side information is different for a second iteration compared to a first iteration.

When the stripe is processed in multiple iterations the weighing can be varied to reflect the increase or decrease in reliability of the side information from one iteration to the next iteration.

An embodiment of the symbol detection method is characterized in that the weighing of the contribution of the side information is higher for the second iteration compared to the first iteration.

In general the reliability of the symbol detection and thus of the side information increases from one iteration to the next iteration. The weighing can be adjusted to reflect this increase in reliability from one iteration to the next iteration.

An embodiment of the symbol detection method is characterized in that the side information is obtained from a row comprising data which is highly protected using redundant coding.

When a row comprising data which is highly protected is comprised in the broad spiral or delimits the broad spiral the side information derived from this data is also more reliable than side information derived from the regular stripes. A higher weighing must therefore be assigned to the side information derived from data which is highly protected compared to side information derived from other data.

An embodiment of the symbol detection method is characterized in that the side information is obtained from a row comprising predefined data.

Predefined data is inherently reliable in detection because errors can be easily corrected.

As a consequence side information derived from predefined data is also reliable. The weighing of side information derived from predefined data can thus be higher than the weighing of side information derived from other data.

An embodiment of the symbol detection method is characterized in that the row comprising data which is highly protected using redundant coding is a guard band.

A guard band often comprises predefined data or is highly protected in order to assure correct detection of the guard band fro purposes of tracking etc. The guard band can thus be put to dual use by deriving side information from the data in the guard band and providing this side information to the symbol detector of the stripe adjacent to the guard band to improve the reliability of the detection.

An embodiment of the symbol detection method is characterized in that the row comprising data which is highly protected using redundant coding is located centrally between the rows forming the set of symbol rows.

Typically a row comprising highly protected data is located such that it delimits the data area. It is however also possible to locate such a row in the middle of the data area. Such a highly protected row can be located in the data area at a position where the stripe wise detection is inherently less reliable, for instance near the center of the data area. In the case of a broad spiral the row would be located near the middle of the broad spiral. Since the reliability of the row comprising highly protected propagates to the adjacent stripes which use, directly or indirectly, use side information from the row comprising highly protected data, such a row can be appropriately positioned to enhance the detection where needed.

An embodiment of the symbol detection method is characterized in that the N-Dimensional channel tube is delimited by multiple guard bands.

By using multiple guard bands the methods outlined in the previous embodiments can be used to start multiple bit detectors in parallel. Near each guard band a bit detector starts, using the side information derived from that guard band, a cascade of bit detectors where each bit detector in the cascade closely trails the previous detector in the cascade. When using the 2 dimensional broad spiral as an example there would be for instance 2 guard bands, a first guards band delimiting the broad spiral at the top and a second guard band delimiting the broad spiral at the bottom. A first cascade of bit detectors starts at the first guard band and propagating the increased reliability down in the cascade towards the second guard band. A second cascade of bit detectors starts at the second guard band and propagating the increased reliability up in the cascade towards the first guard band.

The two cascades of bit detectors would meet somewhere on the broad spiral, for instance at the middle of the broad spiral, each having processed the upper portion of stripes of the broad spiral, respectively the lower portion of stripes of the broad spiral.

In a graphic sense the cascades of bit detectors form a V shape constellation of bit detectors where the open end of the V shape points in the direction of processing of the broad spiral.

Where the two cascades meet one can choose to process a final stripe using either the side information from the cascade having processed the lower portion of stripes, the side information from the cascade having processed the upper portion of stripes, or both side informations.

In addition it is possible to have a bit detector from both cascades process the final stripe.

By working both the upper and lower portion of the broad spiral in parallel the processing time is greatly reduced.

An embodiment of the symbol detection method is characterized in that side information is derived from each guard band of the multiple guard bands.

A symbol detector using one of the embodiments of the method according to the invention benefits from a decrease in time required to process the broad spiral or other N-dimensional data.

A playback device using a symbol detector according to the invention benefits from a decrease in time required to process the broad spiral or other N-dimensional data.

A computer program implementing a symbol detector using the methods of the present invention would benefit from a decrease in time required to process the broad spiral of other N-dimensional data.

It should be noted that the channel output is not necessarily sampled on a lattice, nor is it necessary that the channel output are sampled on a similar lattice as the lattice of channel inputs (recorded marks). E.g. the channel outputs may be sampled according to a lattice hat is shifted with respect to the lattice of channel inputs (recorded marks), e.g. sampling may take place above edges of the cells of a hexagonal lattice. Also, (signal) dependent oversampling may be applied with higher spatial sampling densities in certain directions as compared to other directions, where these directions need to be aligned with respect to the lattice of signal inputs (recorded marks).

1. detected symbols are channel symbols.

2. detected symbols are a linear function of the channel symbols.

3. detected symbols are a linear function of the channel symbols and estimates from preceding iterations of those channel symbols.

4. detected symbols are a linear function of the channel symbols and estimates from preceding iterations of a linear function of the channel symbols.

The invention will now be described based on figures.

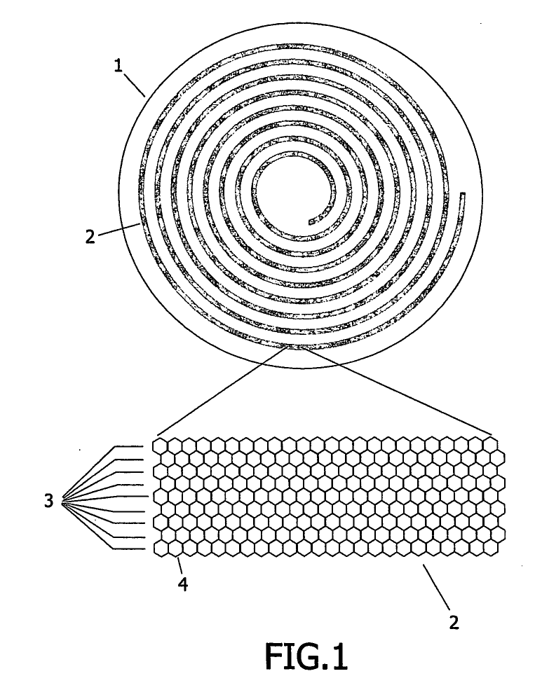

FIG. 1 shows a record carrier comprising a broad spiral.

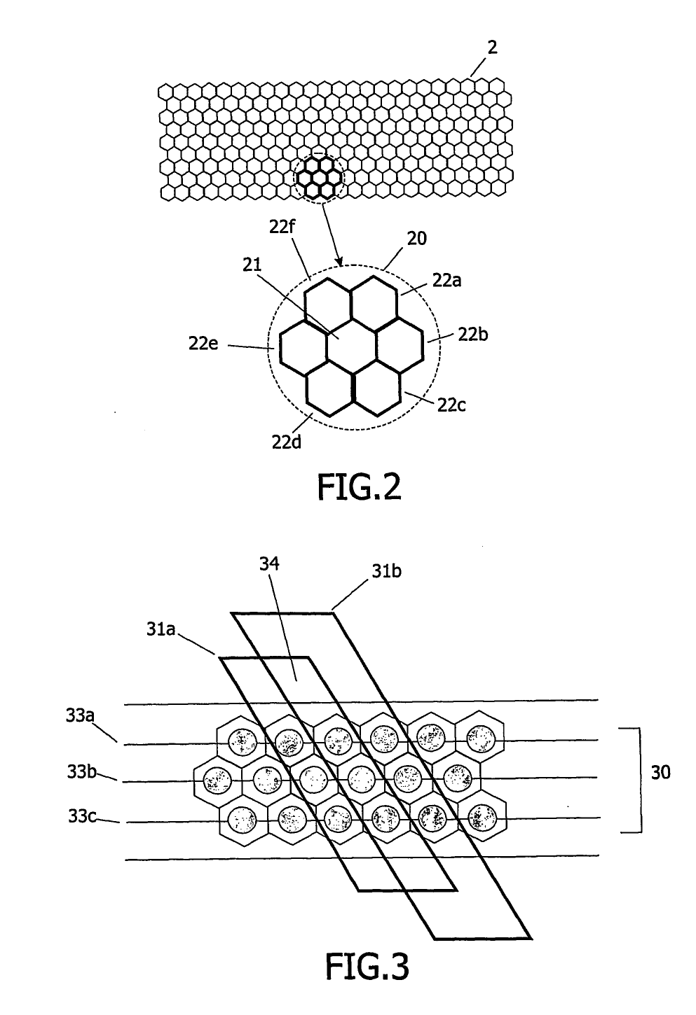

FIG. 2 shows the contributions of leaked away signal energy.

FIG. 3 shows the states and branches for a viterbi detector in a three row stripe.

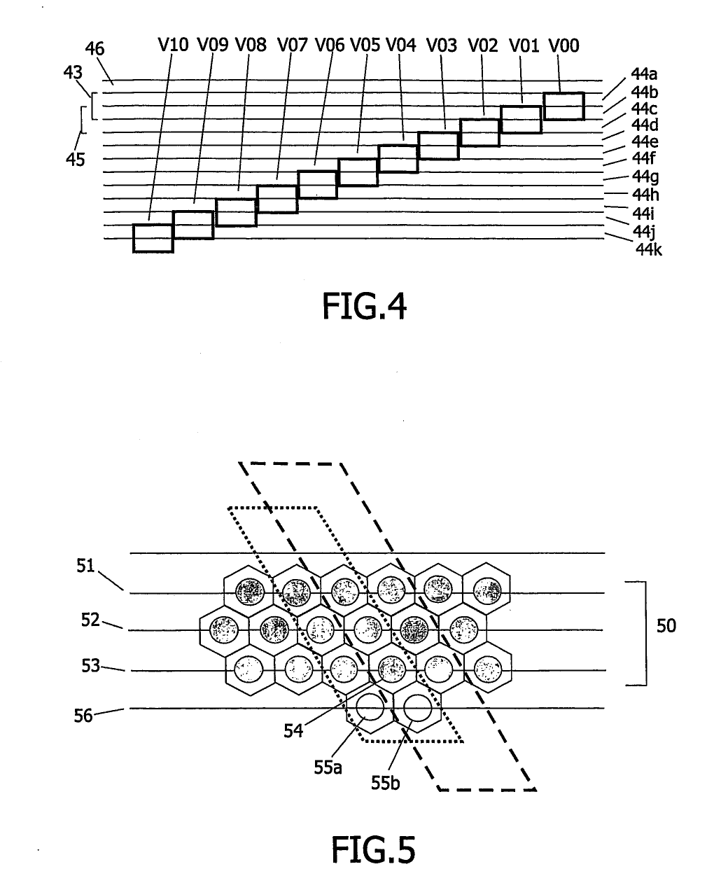

FIG. 4 shows multiple detectors processing a broad spiral.

FIG. 5 shows the reduction of weights in a stripe wise bit detector

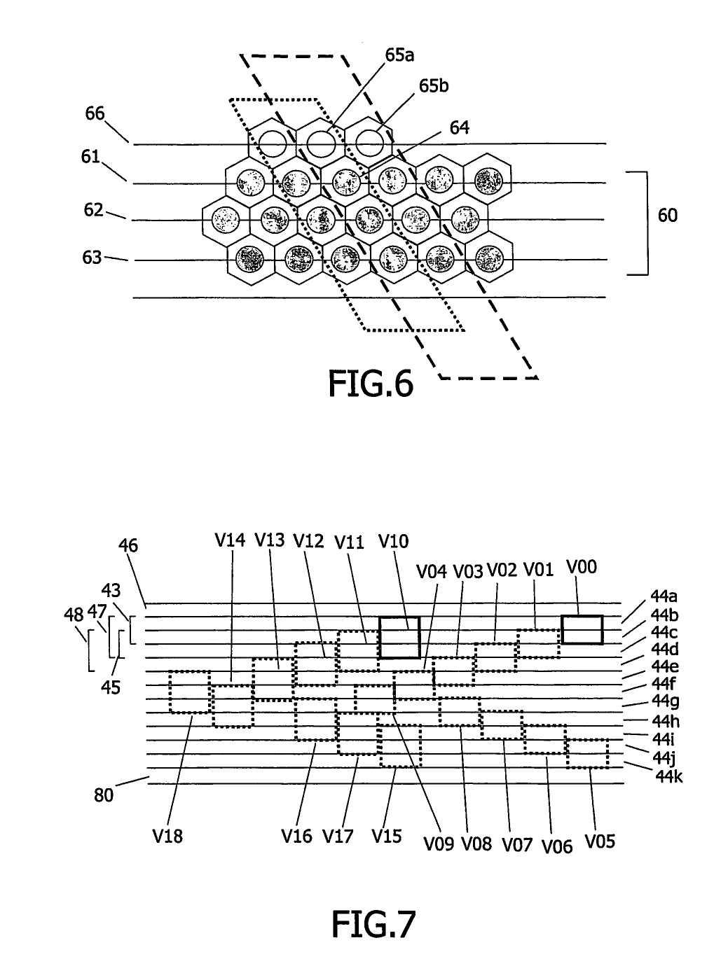

FIG. 6 shows the extension of the computation of branch metrics with samples of the signal waveform at bits in the bit row above the stripe.

FIG. 7 shows a stripe wise bit detection along a broad spiral where the stripe is oriented in a different direction.

FIG. 1 shows a record carrier comprising a broad spiral.

The invention concerns with an extension of the concept of branch metrics to be used for the processing along a Viterbi-trellis of a stripe, involving (i) signal waveform samples of bits outside of the stripe, thus not belonging to the states of the Viterbi processor for the stripe considered and (ii) the introduction of reduced weights smaller than the maximum weight (set equal to 1) for the separate terms in the branch metric that are related to the different bit-rows within the stripe, and (iii) the introduction of cluster-driven weights due to signal-dependent noise characteristics.

The context of this invention is the design of a bit-detection algorithm for information written in a 2D way on a disc 1 or a card. For instance, for a disc 1, a broad spiral 2 consists of a number of bit-rows 3 that are perfectly aligned one with respect to the other in the radial direction, that is, in the direction orthogonal to the spiral 2 direction. The bits 4 are stacked on a regular quasi close-packed two-dimensional lattice. Possible candidates for a 2D lattice are: the hexagonal lattice, the square lattice, and the staggered rectangular lattice. This description is based on the hexagonal lattice because it enables the highest recording density.

For ambitious recording densities the traditional “eye” is closed. In such a regime, the application of a straightforward threshold detection will lead to an unacceptably high bit error rate (10⁻² to 10⁻¹, dependent on the storage density), prior to ECC decoding. Typically, the symbol or byte error-rate (BER) for random errors in the case of a byte-oriented ECC (like the picket-ECC as used in the Blu-Ray Disc Format, BD) must be not larger than typically 2 10⁻³; for an uncoded channel bit stream, this corresponds to an upper bound on the allowable channel-bit error rate (bER) of 2.5 10⁻⁴.

On the other hand, full-fledged PRML type of bit-detectors would require a trellis which is designed for the complete width of the broad spiral 2, with the drawback of an enormous state-complexity. For instance, if the horizontal span of the tangential impulse response along the direction of the broad spiral 2 is denoted by M, and if the broad spiral consists of N_{row} bit-rows, then the number of states for the full-fledged “all-row” Viterbi bit-detector becomes 2ˆ((M-1) N_{row}) (where ˆ denotes exponentiation). Each of these states has also 2ˆ(M N_{row}) predecessor states, thus in total the number of branches or transitions between states equals 2ˆ(M N_{row}). The latter number (number of branches in the Viterbi trellis) is a good measure for the hardware complexity of a 2D bit-detector.

Ways to largely circumvent this exponentially growing state-complexity are the breakdown of the broad spiral 2 into multiple stripes. The state-complexity can be reduced by a stripe-based PRML-detector, and iterating from one stripe towards the next. Stripes are defined as a set of contiguous “horizontal” bit-rows in the broad spiral. Such a bit-detector is shortly called a stripe-wise detector. The recursion between overlapping stripes, the large number of states, i.e. 16 for a stripe of 2 rows, and 64 states for a stripe of 3 rows, and the considerable number of branches, i.e. 4 for a stripe of 2 rows, and 8 for s stripe of 3 rows, and the recursive character of each individual PRML detector make that the hardware complexity of such a detector can still be quite considerable.

FIG. 2 shows the contributions of leaked away signal energy.

The signal-levels for 2D recording on hexagonal lattices are identified by a plot of amplitude values for the complete set of all hexagonal clusters possible. An hexagonal cluster 20 consists of a central bit 21 at the central lattice site, and of 6 nearest neighbour bits 22a, 22b, 22c, 22d, 22e, 22f at the neighbouring lattice sites. The channel impulse response is assumed to be isotropic, that is, the channel impulse response is assumed to be circularly symmetric. This implies that, in order to characterize a 7-bit hexagonal cluster 20, it only matters to identify the central bit 21, and the number of “1”-bits (or “0”-bits) among the nearest-neighbour bits 22a, 22b, 22c, 22d, 22e, 22f (0, 1, . . . , 6 out of the 6 neighbours can b a “1”-bit). A “0”-bit is a land-bit in this description.

Note that the isotropic assumption is purely for the purpose of concise presentation. In a practical drive with a tilted disc, the 2D impulse response can have asymmetry. There are two solutions for the latter issue: (i) to apply a 2D equalizing filter restoring a rotationally symmetric impulse response, and (ii) application of a larger set of reference levels to be used in the branch metric computation, wherein each rotational variant of a given cluster has its own reference level; for this general case, for a 7-bit cluster, consisting of a central bit 21 and its six neighbours 22a, 22b, 22c, 22d, 22e, 22f, we will have 2ˆ7=128 reference levels, instead of the 14 reference levels in case of the isotropic assumption of above.

The channel bits that are written on the disc are of the land type (bit “0”) or of the pit-type (bit “1”). With each bit a physical hexagonal bit-cell 21, 22a, 22b, 22c, 22d, 22e, 22f is associated, centered around the lattice position of the bit on the 2D hexagonal lattice. The bit-cell for a land-bit is a uniformly flat area at land-level; a pit-bit is realized via mastering of a (circular) pit-hole centered in the hexagonal bit-cell. The size of the pit-hole is comparable with or smaller than half the size of the bit-cell. This requirement eliminates the “signal folding” issue, which would arise for a pit-hole that covers the full area of the hexagonal bit-cell 21, 22a, 22b, 22c, 22d, 22e, 22f : in such case, both for a cluster of all zeroes (all-land) as well as for a cluster of all ones (all-pit), a perfect mirror results, with identical signal levels for both cases. This ambiguity in signal levels must be avoided since it hampers reliable bit-detection.

For high-density 2D optical storage, the 2D impulse response of the (linearized) channel can be approximated to a reasonable level of accuracy by a central tap with tap-value co equal to 2, and with 6 nearest-neighbour taps with tap-value c₁ equal to 1. The total energy of this 7-tap response equals 10, with an energy of 6 along the tangential direction (central tap and two neighbour taps), and an energy of 2 along each of the neighbouring bit-rows (each with two neighbour taps).

From these energy considerations, one of the main advantages of 2D modulation can be argued to be the aspect of “joint 2D bit-detection”, where all the energy associated with each single bit is used for bit-detection. This in contrast to 1D detection with standard cross-talk cancellation, where only the energy “along-track” is being used, thus yielding a 40% loss of energy per bit.

A similar argumentation holds when we consider bit detection at the edges of a 2D stripe (for which we want to output the top bit-row). Of the order of 20% of the signal-energy of the bits in the top-row has leaked away in the samples of the signal waveform of the two samples in the bit-row just above the stripe: these two samples are located at nearest neighbour sites of the bit in the top row of the current stripe. The other 20% leaking away from the top bit-row is leaking away in the bit-row below the top bit-row in the stripe: this energy is used because the stripe of at least two bit-rows wide comprises also the bit-row below the top bit-row of the stripe. Consequently, not using the leaked away information, that has been leaking away in the “upward” direction (when the top bit-row is the output of the considered stripe), would lead to a loss in bit-detection performance at the top row of the stripe.

The solution to the above drawback is to include the HF-samples in the bit-row above the stripe in the computation of the figure-of-merit. Note that only the samples of the signal waveform of that row do matter here, and that the bits in that row are not varied since they do not belong to the set of bits that are varied along the trellis and states of the Viterbi-detector for the stripe considered. Denoting the row-index of the bit-row above the stripe by l-l, the branch metric is denoted by (with the running index j now starting from “−1”):

$${β}_{mn} = {\sum }_{j = - 1}^{2} {w}_{j} {\vert {HF}_{k , l + j} - RL ( {\sum }_{m} -> {\sum }_{n} , j , l ) \vert}^{2}$$

This extension of the computation of the branch metrics with inclusion of the row of signal samples in the bit-row above the stripe is schematically drawn in FIG. 6. Note that in the computation of the reference levels, all the required bits within the stripe are set by the two states that constitute a given branch, and all the required bits outside the stripe are determined by the previous stripe in the current iteration of the stripe-wise bit-detector, or by the previous iteration of the stripe-wise bit-detector.

For the sake of completeness, note that the above description applies to a top-to-bottom processing of the stripes, wherein the output of each stripe is its top bit-row, and the extra bit-row that is accounted for in the branch metrics, is the row just above the stripe, with index j=−1. However, for the opposite processing order, from bottom-to-top, the output of each stripe is its bottom bit-row, and the extra bit-row that is accounted for in the branch metrics, is the row just below the stripe, with index j=3 (for a 3-row stripe).

FIG. 3 shows the states and branches for a viterbi detector in a three row tripe.

First the basic structure of the trellis as shown in FIG. 3 is explained, addressing the practical case of a 3-row stripe 30. The tangential span of the 2D impulse response is assumed to be 3 bits wide, a situation that meets the practical conditions for the high-density recording on a hexagonal grid. A state 31a, 31b is specified by two columns extending over the full radial width of 3 rows 33a, 33b, 33c of the stripe 30. There are thus in this example exactly 2ˆ6=64 states. The pace of the Viterbi bit-detector goes with the frequency of emission of a 3-bit column 34. Emission of a 3-bit column 34 corresponds with a state transition from a so-called departure state Σₘ 31a to a so-called arrival state Σₘ 31b. For each arrival state 31b, there are exactly 8 possible departure states 31a and thus 8 possible transitions. A transition between two states 31a, 31b is called a branch in the standard Viterbi/PRML terminology. For each transition, there are thus two states and thus a total of 9 bits that are completely specified by these two states. For each branch, there are a set of reference values which yield the ideal values of the signal waveform at the branch bits these ideal values would apply if the actual 2D bit-stream along the stripe 30 would lead to the considered transition in the noise free case. With each transition a branch metric can be associated which gives a kind of “goodness-of-fit” or “figure-of-merit” for the considered branch or transition based on the differences that occur between the observed “noisy” signal waveform samples, denoted by HF, and the corresponding reference levels which are denoted by RL. It should be noted that the noise on the observed samples of the waveform can be due to electronic noise, laser noise, media noise, shot noise, residual ISI beyond the considered span of the 2D impulse response etc. It is common practise to consider as the branch bits, at which these differences for the figure-of-merit are to be measured, the bits that are common to both states 31a, 31b that constitute the branch: in FIG. 3, this would be the 3 bits of the column at the intersection of the two states 31a, 31b. Thus, if k denotes the tangential index at the position of the intersection column, and l denotes the top bit-row 33a of the stripe 30, the branch metric βₘₙ between the state Σₘ 31a and the state Σₙ 31b is given by:

$${β}_{mn} = {\sum }_{j = 0}^{2} {\vert {HF}_{k , l + j} - RL ( {\sum }_{m} -> {\sum }_{n} , j , l ) \vert}^{2}$$

The above formula is based on the assumption of a quadratic error measure for the figure-of-merit (L₂-norm), which is optimum for the assumption of additive white aussian noise (AWON). It is also possible to use or error measures, like the absolute value of the difference (known as L₁-norm). For the determination of a reference level for a bit at a given location k, l+j on the 2D lattice, the values of the six surrounding bits 22a, 22b, 22c, 22d, 22e, 22f around the location k, l+j are needed together with the value of the central bit 21: these 7 bits 21, 22a, 22b, 22c, 22d, 22e, 22f uniquely specify the reference level to be used for the considered state transition or branch at the considered bit-location 21.

FIG. 4 shows multiple detectors processing a broad spiral.

The standard way of operation of the stripe-wise bit-detector will now be described. A stripe 41a, 41b, 41c consists of a limited number of bit-rows 42a, 42b. For FIG. 4, the practical case of a stripe comprising two bit-rows in a stripe. Note that in FIG. 4, a bit-row is bounded by two horizontal lines at its edges. The number of stripes is equal to the number of bit-rows in the case of two bit rows per stripe. A set of Viterbi bit-detectors V00, V01, V02 is devised, one for each stripe. The bits outside of a given stripe that are needed for the computation of the branch metrics, are taken from the output of a neighbouring stripe, or are assumed to be unknown. In a first iteration the unknown bits may be set to zero. The first top-stripe 43, containing as its top row, the bit-row 44a closest to the guard band is processed by bit detector V00 without any delay at its input; it uses the bits of the guard band as known bits. The output of the bit detector V00 processing the first stripe are the bit-decisions in the first bit-row 44a. The second stripe 45 contains the second row 44b and the third bit-row 44c, and is processed by the second bit detector V01 with a delay that matches the back-tracking depth of the Viterbi-detector of the first stripe 43, so that the detected bits from the output of the bit detector V00 processing the first stripe 43 can be used for the branch metrics of the second stripe 45. This procedure is continued for all stripes in the broad spiral 2. The full procedure from top to bottom of the broad spiral 2 is considered to be one iteration of the stripe-wise detector. Subsequently, this procedure can be repeated starting again from the guard band 46 at the top: for the bits in the bit-row just below the bottom of a given stripe, the bit-decisions from the previous iteration can be used.

In a top-to-bottom processing of successive stripes, the last stripe processor V10 is assumed to output its top bit-row. Another implementation is possible here: the bottom stripe bit detector V10 could be omitted, and alter the 2-row stripe processor V09 to process the three bottom bit rows 44i, 44j, 44k, thus processing the two bottom rows 44j, 44k of the broad spiral 2 such that it outputs both rows simultaneously.

FIG. 5 shows the reduction of weights in a stripe wise bit detector

In FIG. 4 it has been shown that a stripe being processed is shifted from the top of the broad spiral in the downward direction towards the bottom of the spiral. The stripe being processed shifts row per row downwards. Each stripe has as its output the bit-decisions of the top bit-row of the stripe which is the most reliable. That output bit-row is also used as side-information for the bit detection of the next stripe which is the stripe which is shifted one bit-row downwards. The bit-row just across the bottom of the stripe on the other hand still needs to be determined in the current iteration, so only the initialisation bit-values can be used in the first iteration of the stripe-wise bit-detector, or in any subsequent iteration. The bit-decisions resulting from the previous iteration of the stripe-wise bit-detector can be used for that bit row. Therefore, in FIG. 5 the bit-decisions of the three row stripe wise bit detector V02 in the upper bit-row 51 are more reliable than the bit-decisions in the bottom bit-row 53. This is the reason why the output of one stripe is its top bit-row. Also, for the computation of the required reference levels in the bottom bit-row, we need as explained in FIG. 2, the six nearest neighbour bits of the branch bit 54 in the bottom bit-row; two neighbour bits 55a, 55b of these nearest neighbour bits are located in the bit-row 56 just below the stripe considered, and only preliminary bit-decisions, for instance from the previous iteration, are available for these neighbour bits 55a, 55b. Consequently, in case of bit-errors in these two neighbour bits 55a, 55b in the bit-row 56 below the current stripe 50, these errors will affect the selected branches in the surviving path along the Viterbi trellis: actually, the bit-errors in these two neighbour bits 55a, 55b may be compensated by selecting the wrong bits in the states along the stripe, so that the error measure at the bottom branch bit can be kept low enough. Unfortunately, this balancing will propagate errors towards the top bit-row 51 of the stripe 50, which should be prohibited.

In order to prevent the propagation of errors towards the top bit row 51 of the stripe 50 the relative weight for the bottom branch bit in the figure-of-merit is reduced from the full 100%, i.e. a weighting of 1, to a lower fraction. With w₁ denoting the weight of the branch bit in the i-th row of the stripe, the branch metric becomes:

$${β}_{mn} = {\sum {w}_{j}}_{j = 0}^{2} {\vert {HF}_{k , l + j} - RL ( {\sum }_{m} -> {\sum }_{n} , j , l ) \vert}^{2}$$

By choosing the weight of the bottom row 53 in the stripe 50 to be much lower than 1, the negative influence of the unknown or only preliminary known bits 55a, 55b in the bit-row 56 just below the current stripe 50 is largely reduced. The weights of the respective contributions of the signal waveforms to the branch metrics can also be varied from one iteration to the next because the bit-decisions at the surrounding bits become gradually more and more reliable.

For the sake of completeness, note that the above description applies to a top-to-bottom processing of the stripes, wherein the output of each stripe is its top bit-row, and the weight of the bottom bit-row is reduced. However, for the opposite processing order, from bottom-to-top, the output of each stripe is its bottom bit-row, and the weight of the top bit-row is reduced.

Further more, when the processing of the stripe comprises side information from both adjacent stripes, the weight of the top bit row and the bottom bit-row are both reduced.

In detection theory, it is a well-known known fact that in an optimal Viterbi detector, the branch metrics are (negative) log-likelihoods of the channel input bits given the observed channel output values. The branch metric formula

$${β}_{mn} = {\sum }_{j = 0}^{2} {\vert {HF}_{k , l + j} - RL ( {\sum }_{m} -> {\sum }_{n} , j , l ) \vert}^{2}$$

derives its validity from the assumption that the noise is Additive, Gaussian and White. The squares inside the sum above stem from the logarithm of the Gaussian probability density function of the noise gₘₙ which also contains a square,

$$- log ( Pr \{ {g}_{mn} = g \} ) = \frac{1}{2} log ( 2 π N ) + \frac{{g}^{2}}{2 N}$$

The whiteness assumption of the noise implies that different noise components are statistically independent, so that their probability density functions can be multiplied. Therefore, their log-likelihood functions can be added, as in the βₘₙ formula.

The problem we want to consider here, is that e.g. for an optical recording the variance of the noise N may depend on the central input bit of a given channel output HF_{k,l+j} and its cluster of nearest neighbour inputs. For example, in case laser noise is dominant, larger channel outputs HF_{k,l+j} carry more (multiplicative) laser noise (which is usually referred to as ‘RIN’, “relative intensity noise”). This leads to the question what value of the noise N to use in the branch metric formula for βₘₙ?

The solution to this problem is very simple. Based on a table of the cluster-dependent noise variances, we make a table for the noise variance N(Σₘ→Σₙ, j) as a function of the state transition (Eₘ→Fₙ) and the row index j, and we divide by the adjusted value of N in the branch metric formula,

$${β}_{mn} = {\sum {w}_{j}}_{j = 0}^{2} \frac{{\vert {HF}_{k , l + j} - RL ( {\sum }_{m} -> {\sum }_{n} , j , l ) \vert}^{2}}{N ( {\sum }_{m} -> {\sum }_{n} , j , l )}$$

When the noise is really dependent on the cluster and on the central input bit of a given channel output, taking account of this as in the branch metric formula above makes the branch metrics more closely equal to the log-likelihood functions as stated in the introduction of this subsection. This in general results in an improvement of the resulting bit error rate at the bit-detector output.

FIG. 6 shows the extension of the computation of branch metrics with samples of the signal waveform at bits in the bit row above the stripe.

In FIG. 4 it has been shown that a stripe is shifted from the top of the broad spiral in the downward direction towards the bottom of the spiral. The stripe wise processing shifts row per row downwards. Each stripe wise detector has as its output the bit-decisions derived from the top bit-row of the stripe which is the most reliable. That output bit-row 66 of the previous stripe is also used as side-information for the bit detection of the next stripe 60 which is the stripe which is shifted one bit-row downwards. As shown in FIG. 6 the stripe 60 comprises three bit rows 61, 62, 63. In FIG. 5 it was explained that the weighting of the bottom bit row 63 is reduced to prevent errors caused by the higher uncertainty associated with the bits in the lower bit row 63 from propagating upward.

The output bit-row 66 as produced by the bit detection of the previous stripe has a higher reliability and the bits 65a, 65b of this bit row 66 can be used as side information for the processing of the next stripe 60. Especially when the output bit row 66 as produced by the bit detection of the previous stripe is derived from a guard band. The guard band has very well encoded information or even predefined data resulting in a 100% reliability of the side information used in the bit detection of the next stripe 60.

In the particular case of a broad spiral with two guard bands with bits that are known to the detector, the bit-reliability of the two anchor bit-rows is 100%. Another example is the case of a 2D format with an extra bit-row in the middle of the spiral, that is encoded such that it has a higher bit-reliability than the other rows; then, two V-shaped progressions of stripes can be devised, one operating between the center bit-row and the upper guard band, the other operating between the same center bit-row and the lower guard band. For instance, the center bit-row may be channel encoded with a 1D runlength limited (RLL) channel code that enables robust transmission over the channel: for instance, a d=1 RLL channel code removes some of the clusters (those with a “1” central bit and all six “0”'s as neighbour bits, and vice versa) in the overlap area of the signal patterns, hereby increasing the robustness of bit-detection on the one hand, but reducing the storage capacity for that row on the other hand because of the constrained channel coding.

During back-tracking of a Viterbi-processor for a given stripe, it is an option to output all bit-rows of the stripe so that a bit-array with the most recent bit-estimates are stored. The purpose of this measure is to achieve a more uniform architecture for the Viterbi-processors in the top-halt bottom-half and central area of a V-shaped bit-detection scheme.

Prior to any Viterbi bit-detection, it is advantageous to have some preliminary bit-decisions albeit at a relatively poor bit-error rate (bER) performance. For instance, at one side of each stripe, bits that have been determined from the previous stripe or are set to zero when the stripe is located directly next to the guard band; at the other side of the stripe, bit-decisions are needed in order to be able to derive reference levels for the bits in the neighbouring bit stripe within the stripe: these bit-decisions can be derived from a previous iteration of the stripe-wise bit-detector, or from preliminary bit-decisions when the first iteration of the stripe-wise bit-detector is being executed. These preliminary decisions can just be obtained by putting all bits to zero, which is not such a clever idea.

A better approach is to apply threshold detection based on threshold levels (or slicer levels) that depend on whether the row is neighbouring the guard band (consisting of all zeroes) or not. In the case of a bit-row neighbouring the guard band, some cluster-levels are forbidden. Consequently, the threshold level is shifted upwards. It is computed as the level between the cluster-level for a central bit equal to 0 and three 1 -bits as neighbour, and the cluster-level for a central bit equal to 1 and one 1-bit as neighbour. The expected bit-error rate of this simple threshold detection is then, for this case, equal to 2/32, which is about 6%. In the case of a bit-row that is not neighbouring the guard-band, the threshold level is computed as the level between the cluster-level for a central bit equal to 0 and four 1-bits as neighbour, and the cluster-level for a central bit equal to 1 and two 1-bits as neighbour. The expected bit-error rate of this simple threshold detection is then, for this case, equal to 14/128, which is about 11%. Although these bERs are quite high, they are considerably better, especially at the bit-rows neighbouring the guard bands, than the 50% bER obtained through coin tossing. These preliminary bit-decisions obtained prior to the execution of the stripe-wise bit-detector can also be used as input for the adaptive control loops of the digital receiver (e.g. for timing recovery, gain- and offset-control, adaptive equalization etc.) Note that the above derivation of the proper slicer levels depends on the actual 2D storage density chosen and the resulting overlap of signal levels in the “Signal Patterns”.

In FIG. 7a different diagonal orientation of the stripe on the 2D hexagonal lattice is shown. For such diagonal orientations, the shifting of the stripe 71 comprising the three bit rows 72a, 72b, 72c takes place along the direction of the broad spiral 70. This implies that the Viterbi processing with state-termination at the guard bands 73, 74 where the bits are known to be zero, or a predefined value or a variable error protected value, has to be completed before the shifting over the distance of one bit along the tangential direction of the broad spiral 70 can take place. The latter aspect is a real disadvantage with respect to parallelization of the hardware implementation. Different executions of the stripe-wise bit-detector, operating along different directions, can be cascaded one after the other. Also, more oblique orientations than the ones shown in FIG. 7 can be devised. The orientation shown in Figure is one of the possibilites oriented along the basic axes of the 2D hexagonal lattice, with angles of exactly 60 degrees between them.

One iteration of the stripe-wise bit-detector may consist as described above out of a successive processing of stripes 43, 45 starting from the guard band 46 on top of the broad spiral towards the guard band 80 at the bottom of the broad spiral resulting in a linear row of detectors V00, V01, V02, V03, V04, V05, V06, V07, V08, V09, V10 diagonal across the broad spiral as shown in FIG. 4. Alternatively, one can start with stripes 43, 81 from both guard bands 46, 80 and successively process a number of stripes proceeding from both sides towards the middle of the broad spiral. Successive detectors V00, V00a, V01, V01a, V02, V02a, V03, V03a, V04, V04a of the stripes are arranged in a V-shape as can be seen in FIG. 8 for the practical case of a 11-row broad spiral and stripes 43, 45 consisting of two bit-rows. The Viterbi-detectors V00, V00a, V01, V01a, V02, V02a, V03, V03a, V04 are cascaded one after the other with mutual delay to allow for back-tracking of the respective detectors, and the cascade starts from the top guard-band 46 towards the center of the broad spiral; each of these Viterbi-detectors V00, V01, V02, V03, V04 has as output the bit-decisions for the top bit-row. Each of these Viterbi-detectors V00, V01, V02, V03, V04 also uses the signal waveform samples at the bit-row above the stripe as additional extra row in the branch metrics; the weight of the signal waveform samples in the bottom row of the stripe is reduced below the maximum value (set equal to 1). In analogy, the Viterbi-detectors V00a, V01a, V02a, V03a are cascaded one after the other (also with mutual delay for back-tracking purposes) starting from the bottom guard-band 80 towards the center of the broad spiral; each of these detectors V00a, V01a, V02a, V03a has as output the bit-decisions for the bottom bit-row. Each of these Viterbi-detectors V00a, V01a, V02a, V03a also uses the signal waveform samples at the bit-row below the stripe as additional extra row in the branch metrics; the weight of the signal waveform samples in the top row of the stripe is reduced below the maximum value (set equal to 1). These two sets of cascaded Viterbi-detectors V00, V01, V02, V03, V00a, V01a, V02a, V03a have a mutual mirror-type of relationship. Finally, the two cascades of detectors for the stripes are terminated in the middle of the broad spiral with a last detector V04a for the last stripe 44f, which is the only detector for a stripe that has as output its two bit-rows, and which has extra exterior bit-rows on both sides of the stripe (of which the signal waveforms are included in the computation of the branch metrics of that stripe); also the weights of all signal waveforms at the branch-bits are set equal to the maximum value 1 (since the bit-rows at both sides of this stripe have been determined during execution of the two cascades of Viterbi-detectors in all previous stripes).

With the V-shaped stripe-wise bit-detector V00, V01, V02, V03, V00a, V01a, V02a, V03a, V04, V04a, the propagation direction of “bit-reliability” is from the known bits of the guard band 46, 80 towards the bit-row 44f in the middle of the broad spiral, which are thus the largest distance from the guard bands: the “known” information is propagated from both sides towards the middle, which is a better approach than propagating from top to bottom of the broad spiral.

In the particular case of a broad spiral with two guard bands 46, 80 with bits that are known to the detector, the bit-reliability of the two anchor bit-rows 46, 80 is 100%. To utilize both guard bands 46, 80 the linear row of trailing detectors can be reshaped into a V shape as shown in FIG. 8. This not only utilizes the reliability of both guard bands 46, 80 by propagating the reliability through the increased reliability of the side information that each detector provides to the next, trailing detector, it also reduces the total time required to perform the detection since the first detectors V00, V00a, V01, V01a, V02, V02a, V03, V03a work in parallel providing the last detectors V04, V04a sooner with the required side information. As an alternative to the last two detectors V04, V04a a single detector that processes the middle three bit rows 44e, 44f, 44g at the same time, instead of just two rows, can be used. The overall reliability of the V shape is higher than in the case of the regular linear row of detectors because the final detector or detectors V04, V04a receive their side information through less intermediate detectors V00, V00a, V01, V01a, V02, V02a, V03, V03a.

The idea of this subsection can be generalized in the following way: the stripes can be cascaded as two sets forming a V-shaped configuration between any pair of two bit-rows in the 2D area that have a significantly higher bit-reliability, so that they can serve as anchor points from which successive stripes can propagate in a two-sided way towards each other in the middle area between the two rows with high bit-reliability. In the particular case of a broad spiral with two guard bands 46, 80 with bits that are known to the detector, the bit-reliability of the two anchor bit-rows is 100%. Another example is the case of a 2D format with an extra bit-row in the middle of the spiral, that is encoded such that it has a higher bit-reliability than the other rows; then, two V-shaped progressions of detectors processing the stripes can be devised, one operating between the center bit-row 44f and the upper guard band 46, the other operating between the same center bit-row 44f and the lower guard band 80. For instance, the center bit-row 44f may be channel encoded with a ID runlength limited (RLL) channel code that enables robust transmission over the channel: for instance, a d=1 RLL channel code removes some of the clusters, those with a “1” central bit and all six “0”'s as neighbour bits, and vice versa, in the overlap area of the signal patterns, hereby increasing the robustness of bit-detection on the one hand, but reducing the storage capacity for that row on the other hand because of the constrained channel coding.

During back-tracking of a Viterbi-processor for a given stripe, it is an option to output all bit-rows of the stripe so that a bit-array with the most recent bit-estimates are stored. The purpose of this measure is to achieve a more uniform architecture for the Viterbi-processors in the top-half, bottom-half and central area of a V-shaped bit-detection scheme.

Prior to any Viterbi bit-detection, it is advantageous to have some preliminary bit-decisions albeit at a relatively poor bit-error rate (bER) performance. For instance, at one side of each stripe, bits that have been determined from the previous stripe or are set to zero when the stripe is located directly next to the guard band; at the other side of the stripe, bit-decisions are needed in order to be able to derive reference levels for the bits in the neighbouring bit stripe within the stripe: these bit-decisions can be derived from a previous iteration of the stripe-wise bit-detector, or from preliminary bit-decisions when the first iteration of the stripe-wise bit-detector is being executed. These preliminary decisions can just be obtained by putting all bits to zero, which is not such a clever idea

A better approach is to apply threshold detection based on threshold levels, i.e. slicer levels, that depend on whether the row is neighbouring the guard band consisting of all zeroes or not. In the case of a bit-row 44a, 44k neighbouring the guard band 46, 80, some cluster-levels are forbidden. Consequently, the threshold level is shifted upwards. It is computed as the level between the cluster-level for a central bit equal to 0 and three 1-bits as neighbour, and the cluster-level for a central bit equal to 1 and one 1-bit as neighbour. The expected bit-error rate of this simple threshold detection is then, for this case, equal to 2/32, which is about 6%. In the case of a bit-row that is not neighbouring the guard-band, the threshold level is computed as the level between the cluster-level for a central bit equal to 0 and four 1-bits as neighbour, and the cluster-level for a central bit equal to 1 and two 1-bits as neighbour. The expected bit-error rate of this simple threshold detection is then, for this case, equal to 14/128, which is about 11%. Although these bERs are quite high, they are considerably better, especially at the bit-rows neighbouring the guard bands, than the 50% bER obtained through coin tossing. These preliminary bit-decisions obtained prior to the execution of the stripe-wise bit-detector can also be used as input for the adaptive control loops of the digital receiver (e.g. for timing recovery, gain- and offset-control, adaptive equalization etc.) Note that the above derivation of the proper slicer levels depends on the actual 2D storage density chosen and the resulting overlap of signal levels in the “Signal Patterns”.

1. A stripe wise iterative symbol detection method for detecting symbol values of a data block recorded along an N-dimensional channel tube, N being at least 2, on a record carrier of a set of symbol rows, one dimensionally evolving along a first direction and being aligned with each other along at least a second of N-1 other directions, said first direction together with said N-1 other direction constituting an N-dimensional lattice of symbol positions, wherein a stripe is a subset of a row and at least one neighboring row, the iteration of said stripe wise iterative symbol detection comprises:
estimating the symbol values in a first stripe, using a search based algorithm, a side information derived from a row adjacent to the first stripe, the side information being used in the estimation of said symbol values, characterized in that a weighing of a contribution of the side information is assigned based on a reliability of the side information

2. A stripe wise iterative symbol detection method as claimed in claim 1,
characterized in that the contribution is a contribution to an objective function of the search based algorithm.

3. A stripe wise iterative symbol detection method as claimed in claim 2, characterized in that the search based algorithm comprises the use of contributions internal to the stripe and that the use of the internal contributions comprises assigning an individual weighing of the internal contributions

4. A stripe wise iterative symbol detection method as claimed in claim 1, characterized in that the search based algorithm is a Viterbi algorithm, a sequential decoding algorithm such as a stack algorithm or a Fano algorithm, or a soft-decision output algorithm such as a (Max)(Log)MAP algorithm.

5. A stripe wise iterative symbol detection method as claimed in claim 4, characterized in that the side information is an estimated channel input symbol

6. A stripe wise iterative symbol detection method as claimed in claim 4, characterized in that the side information is likelihood information about a channel input symbol.

7. A stripe wise iterative symbol detection method as claimed in claim 5, characterized in that a further side information, derived from the row adjacent to the first stripe, is being used in the estimation of said symbol values.

8. A stripe wise iterative symbol detection method as claimed in claim 7, characterized in that the further side information comprises channel output values.

9. A stripe wise iterative symbol detection method as claimed in claim 8, characterized in that the channel output values are filtered channel output values

10. A stripe wise iterative symbol detection method as claimed in claim 1, characterized in that a weighing of the contribution of the side information is highest for side information derived from a symbol detection with a highest reliability.

11. A stripe wise iterative symbol detection method as claimed in claim 11, characterized in that the symbol detection with the highest reliability is a symbol detection from a previous iteration.

12. A stripe wise iterative symbol detection method as claimed in claim 10, characterized in that the weighing is based on a distance between a position of a symbol value to be detected and a position of a side information symbol position

13. A stripe wise iterative symbol detection method as claimed in claim 12,
characterized in that the distance is a distance to a most reliable side information position

14. A stripe wise iterative symbol detection method as claimed in claim 10, characterized in that the weighing of the contribution of the side information is different for the second detector compared to the first detector

15. A stripe wise iterative symbol detection method as claimed in claim 10, characterized in that the weighing of the contribution of the side information is different for a second iteration compared to a first iteration.

16. A stripe wise iterative symbol detection method as claimed in claim 15, characterized in that the weighing of the contribution of the side information is higher for the second iteration compared to the first iteration.

17. A stripe wise iterative symbol detection method as claimed in claim 10, characterized in that the side information is obtained from a row comprising data which is highly protected using redundant coding.

18. A stripe wise iterative symbol detection method as claimed in claim 10, characterized in that the side information is obtained from a row comprising predefined data.

19. A stripe wise iterative symbol detection method as claimed in claim 17, characterized in that the row comprising data which is highly protected using redundant coding is a guard band

20. A stripe wise iterative symbol detection method as claimed in claim 17, characterized in that the row comprising data which is highly protected using redundant coding is located centrally between the rows forming the set of symbol rows.

21. A stripe wise iterative symbol detection method as claimed in claim 19, characterized in that the N-Dimensional channel tube is delimited by one or more guard bands.

22. A stripe wise iterative symbol detection method as claimed in claim 19, characterized in that side information is derived from each guard band of the one or more guard bands

23. A symbol detector comprising a first detector comprising estimation means for estimating symbol values in a first stripe, receiving means for receiving side information derived from at least one row adjacent to the first stripe, coupled to the estimation means for providing said side information to the estimation means for use in the estimation of said symbol values and output means for providing further side information, and a second detector comprising further estimation means for estimating symbol values in a second stripe, further receiving means for receiving side information derived from the output of the first detector coupled to the further estimation means for providing said side information to the further estimation means for use in the estimation of said symbol values from the second stripe.

24. A playback device comprising a symbol detector as claimed in claim 23

25. A computer program using one of the method of claim 1.
